(19) United States
(12) Patent Application Publication
(10) Pub. No.: US 2018/0183385 A1
(43) Pub. Date: Jun. 28, 2018

(54) PHOTOVOLTAIC MODULE AND METHOD OF MANUFACTURING A PHOTOVOLTAIC MODULE

(71) Applicant: SolarWorld Industries GmbH, Bonn (DE)

(72) Inventors: Kai-Uwe Potempa, Freiberg (DE); Alexander Fuelle, Chemnitz (DE); Martin Kutzer, Penig (DE)

(21) Appl. No.: 15/847,977

(22) Filed: Dec. 20, 2017

(30) Foreign Application Priority Data
Dec. 23, 2016 (DE) 10 2016 125 637.4

(51) Int. Cl. H02S 40/36; H01L 31/05; H01L 31/18; H01L 31/048

(52) U.S. Cl. CPC H02S 40/36; H01L 31/048; H01L 31/18; H01L 31/05

(57) ABSTRACT

In various embodiments, a photovoltaic module is provided. The photovoltaic module may include a plurality of electrically coupled photovoltaic cell, the photovoltaic cells being arranged next to each other such that a cell gap is formed between the photovoltaic cells in each case, a transparent front cover and a transparent rear cover between which the photovoltaic cells are arranged, a marginal gap being formed between the edge of the covers and the photovoltaic cells directly adjacent thereto, and at the back of the cell, a structure which at least partially covers at least one of a cell gap or a marginal gap, the structure having a decreasing coverage in the direction of a respective photovoltaic cell.

### CROSS-REFERENCE TO RELATED APPLICATION

This application claims priority to German Patent Application Serial No. 10 2016 125 637.4, which was filed Dec. 23, 2016, and is incorporated herein by reference in its entirety.

### TECHNICAL FIELD

Various embodiments relate generally to a photovoltaic module and a process for the production of a photovoltaic module.

### BACKGROUND

A photovoltaic module usually has a large number of electrically coupled photovoltaic cells. The photovoltaic cells are arranged next to each other at a distance from each other, so that a gap is formed between two adjacent photovoltaic cells and between the edge of the photovoltaic module and a respective photovoltaic cell. The photovoltaic cells are usually protected against weathering and mechanical influences by means of a front side cover, a rear side cover and an encapsulation.

Light that passes through the gap and does not hit a photovoltaic cell does not contribute to the generation of electrical energy. The different gaps between the photovoltaic cells and between the photovoltaic cells and the edge of the photovoltaic module thus contribute to a reduction in the electrical energy that can be recovered per area of the photovoltaic module and to a reduction in the power per area of the photovoltaic module.

### SUMMARY

In various embodiments, a photovoltaic module is provided. The photovoltaic module may include a plurality of electrically coupled photovoltaic cell, the photovoltaic cells being arranged next to each other such that a cell gap is formed between the photovoltaic cells in each case, a transparent front cover and a transparent rear cover between which the photovoltaic cells are arranged, a marginal gap being formed between the edge of the covers and the photovoltaic cells directly adjacent thereto, and at the back of the cell, a structure which at least partially covers at least one of a cell gap or a marginal gap, the structure having a decreasing coverage in the direction of a respective photovoltaic cell.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a photovoltaic module according to various examples;

FIG. 1B shows a section of a cross-section of a photovoltaic module according to various examples;

FIGS. 2A and 2B show excerpts of cross-sections of photovoltaic modules according to various examples;

FIGS. 3A to 3H show further sections of cross-sections of photovoltaic modules according to various examples;

FIGS. 4A to 4D show structures in photovoltaic modules according to various examples;

FIG. 5 shows a section of a plan view of a photovoltaic module according to various examples; and

FIG. 6 shows a block diagram of a process for manufacturing a photovoltaic module according to various examples.

### DESCRIPTION

The following detailed description refers to the enclosed drawings, which form part of these and in which specific forms of execution are shown for illustration, in which the invention can be exercised. In this respect, directional terminology such as “top”, “bottom”, “front”, “back”, etc. is used with reference to the orientation of the figure(s) described. Since components of execution forms can be positioned in a number of different orientations, the directional terminology serves as an illustration and is in no way restrictive. It is understood that other forms of execution can be used and structural or logical changes can be made without deviating from the scope of protection of the present invention. It goes without saying that the characteristics of the various exemplary forms of execution described here can be combined with each other, unless otherwise specified. The following detailed description is therefore not to be understood in a restrictive sense, and the scope of protection of this invention is defined by the claims attached.

For the purposes of this description, the terms “connected” and “coupled” are used to describe both a direct and an indirect connection, a direct or indirect connection and a direct or indirect coupling. In the figures, identical or similar elements are provided with identical reference signs, as far as this is appropriate.

According to various examples, one aspect of revelation can be seen in the fact that by means of a structure covering a gap (e. g. a cell gap or a marginal gap), light entering this gap can be reflected in different ways, so that this light can contribute to the generation of electrical energy.

According to various examples of execution, another aspect of the revelation can be seen in the fact that an additional parameter is given by means of a variable covering of a structure, which for example shows a decreasing covering from a gap to a photovoltaic cell. With this parameter, production-related positioning errors in a photovoltaic module and a corresponding width of a structure with a resulting shadowing (due to the structure) can be compensated and compensated.

According to various examples of implementation, another aspect of revelation can be seen in the fact that, by means of a structure with decreasing coverage in the direction of a particular photovoltaic cell, one or more production-related shifts of the parts of a photovoltaic module against each other (e. g. shifts of photovoltaic cells against each other) are less noticeable to the human eye compared with the case where no structure is present or a structure exists which, for example, provides constant transparency.

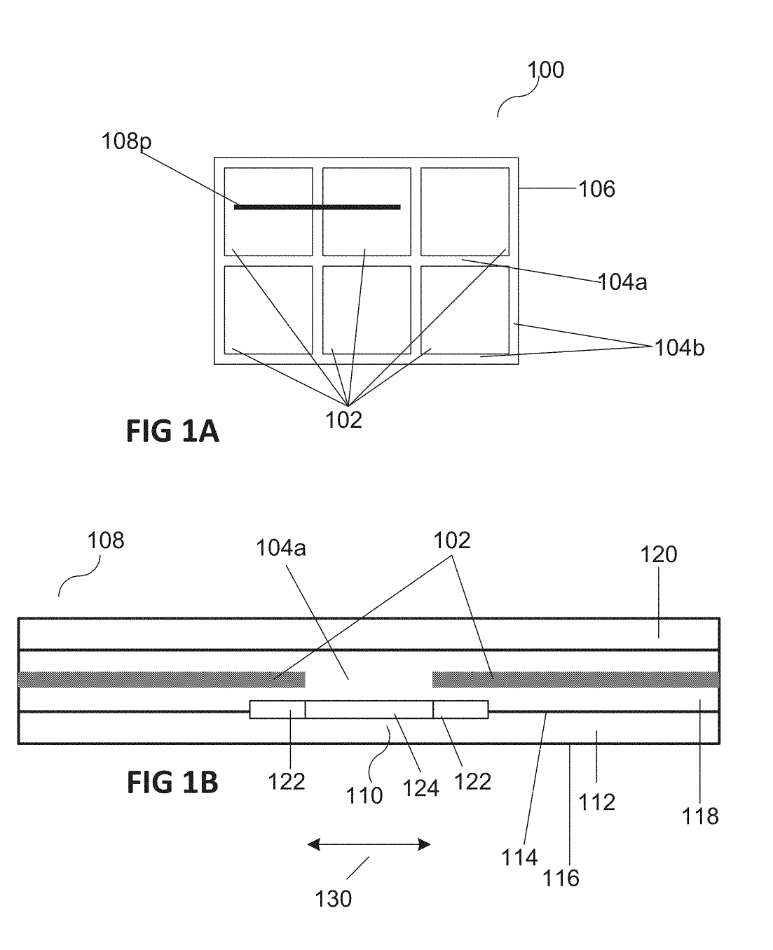

FIG. 1A shows schematically a photovoltaic module 100 according to various examples.

A photovoltaic module 100 can be understood as an electrically connectable device which can have one or more photovoltaic cells 102. The photovoltaic cells 102 can be arranged side by side as shown. The photovoltaic module 100 can be limited by the edge 106. Between at least two photovoltaic cells 102 there can be a cell gap 104a, or between several photovoltaic cells 102 there can be several different cell columns 104a with the same or different dimensions. One or more edge columns 104b may be located between edge 106 and one or more photovoltaic cells 102.

The photovoltaic module 100 can be mounted on a module frame (not shown), for example, a mounting frame. The module frame can be attached to and hold the photovoltaic module 100 at its edge 106 by means of one or more clamps (which can be equipped with a buffer material, such as plastic, a permanently elastic material, soft rubber or an adhesive, in order not to damage the photovoltaic module 100). The module frame can have a mechanically stabilising function and can enable or at least facilitate the installation of the photovoltaic module 100, for example, the installation on a house roof.

A photovoltaic cell 102 (also called solar cell) is a device that converts the radiant energy of light into electrical energy by means of the photovoltaic effect. For example, light can be converted into electrical energy in a visible range in a wavelength range from about 400 nm to about 800 nm and/or in an ultraviolet (UV) range with a wavelength of less than 400 nm and/or in an infrared (IR) range with a wavelength of more than 800 nm, for example up to about 1150 nm, by means of a photovoltaic cell 102. One or more photovoltaic cells 102 can be mono-facial, bifacial or partially bifacial.

One or more photovoltaic cells 102 can be made of (doped) mono-crystalline, multi-crystalline or amorphous silicon on the basis of a substrate. For example, the substrate may also have a (doped) III V semiconductor such as gallium arsenide (GaAs), doped II VI semiconductor such as cadmium telluride (CdTe), doped I-III VI semiconductor such as copper indium di-sulfide (CIS) or copper indium gallium di-selenide (CIGS). In addition, one or more photovoltaic cells 102 can also be organic solar cells or dye solar cells (Gratzel cells). The structure of a photovoltaic cell 102 can be according to the PERC concept (passivated emitter and rear cell) or other cell concepts.

The photovoltaic cells 102 can be electrically coupled to each other (in series and/or parallel). For example, the photovoltaic module can have 100 corresponding electric cables (not shown) and conduct the electrical current generated by the photovoltaic cells 102 to a consumer (not shown) outside the photovoltaic module.

The reference sign 108p shows the position of the section 108 of a cross-section shown in FIG. 1B schematically through the photovoltaic module 100 according to various examples.

The photovoltaic module 100 can have a rear cover 112, an encapsulation 118 and a front cover 120. The rear cover 112 may have a front 114 and a back 116. The rear cover 112, the encapsulation 118 and the front cover 120 can be used for weather protection. The two shown photovoltaic cells 102 can be arranged side by side or adjacent to each other in such a way that the two photovoltaic cells 102 of cell gap 104a are located between the two photovoltaic cells 102. The photovoltaic module 100 can have a structure of 110. Structure 110 may have one or more sub areas 122, which (each) at least partially cover a photovoltaic cell, and may have one or more sub areas 124, which at least partially cover the cell gap 104a.

Under the enclosure 118, the rear cover 112 may be provided, which is glued to the enclosure 118, for example. The front side cover 120 can also be glued to the enclosure 118 above the enclosure 118. The rear cover 112 may contain or consist of glass, such as rolled glass or float glass, or plastic, for example in the form of several laminated foils or plexi-glass. The 120 front panel cover may have or consist of the same material or 112 different materials from the rear panel cover. The optical properties, e. g. the transparency in a wavelength range, the 120 front cover and the 112 rear cover can be adapted to the wavelength of the light to be converted by means of photovoltaic cells 102.

Encapsulation 118 can encapsulate the photovoltaic cells 102 (at least partially) and consist, for example, of ethylene vinyl acetate (EVA). Encapsulation 118 can substantially completely surround one, several or all of the photovoltaic cells 102 (however, it can still permit electrical contacting of the photovoltaic cells 102 through encapsulation 118).

Structure 110 is dealt with in the following figures (among other things).

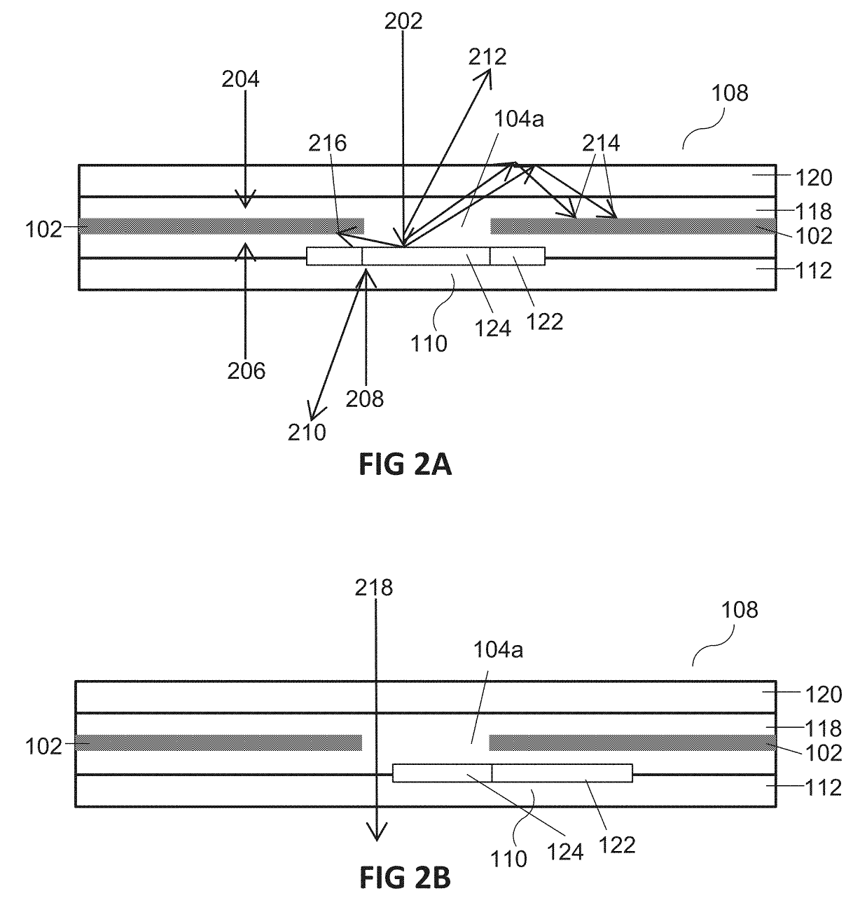

FIG. 2A shows schematically once again the section 108 on FIG. 1B with the outlined courses of light beams.

A light beam 206 can reach (at least in part) through the transparent rear cover 112 and through the transparent enclosure 108, for example, a rear side of the photovoltaic cell 102. In bifacial photovoltaic cells 102 in particular, the light of light beam 206 can be converted into electrical energy in photovoltaic cell 102.

A further light beam 208 can reach structure 110 at least partially, for example, through the transparent rear cover 112 and can be reflected in a light beam 210 and thus not contribute to the generation of electrical energy.

A light beam 204 can reach (at least partially) through the transparent front side cover 120 and through the transparent enclosure 108, for example, a front face of the photovoltaic cell 102, whereby the light of the light beam 204 can be converted into electrical energy in the photovoltaic cell 102.

A light beam 202 can enter the cell gap 104a between two photovoltaic cells 102 and structure 110. If no structure 110 were present, the light of light beam 204 would pass through the photovoltaic module 110 without the light being converted into electrical energy. Thus, the area of the photovoltaic module 100 would not be used optimally. Structure 110, which covers the cell gap 104a, can be used to circumvent this problem or at least mitigate the effects.

The light beam 202 can be reflected at least partially from structure 110. For example, reflection may depend on where light beam 202 hits structure 110, on the angle at which light beam 202 hits structure 110, on the surface texture of structure 110, and on the distance between structure 110 and a photovoltaic cell 102.

For example, light beam 202 can hit (at least partially) the rear of the photovoltaic cell 102 in a reflected light beam 216. In various embodiments, bifacial photovoltaic cells or partially bifacial photovoltaic cells can increase the output per area of a photovoltaic module 100.

Light beam 202, for example, can be reflected by structure 110 (at least partially) in a reflected beam 212 and cannot contribute to the generation of electrical energy.

For example, light beam 202 can reach (at least partially) the front face of photovoltaic cell 102 in one of the two reflected beams 214 and thus contribute to the generation of electrical energy. The two reflected beams 214 are examples of the exploitation of reflection, such as total reflection, at interfaces between areas with different optical refractive indices, such as the interface between the front cover 120 and air (or, for example, a material such as a foil on the front cover 120).

A structure 110 can thus be used for the photovoltaic module 100 in several ways to make light, which would have entered through the cell gap 104a without a structure 110 and thus would not have contributed to the generation of electrical energy, usable for the photovoltaic module 100 and thus increase the power per area of the photovoltaic module 100.

FIG. 2B shows schematically the section 108 with a shifted structure 110.

Due to production conditions, structure 110 may be removed from a desired position (e. g. the position shown in FIG. 2A), as shown in FIG. 2B. For example, subarea 122 of structure 110, which covers a photovoltaic cell 102, may be larger in area than subarea 122, which covers the cell gap 104a.

As shown, the cell gap 104a can no longer be completely covered by structure 110 and a beam of light 218 can pass through the photovoltaic module 100 without contributing to the generation of electrical energy.

An example of a cause of such a production-related shift can be found in the formation of encapsulation 118. For example, an enclosure 118 can/must be heated in order to achieve the corresponding effect of encapsulation or to form an enclosure. When heated, the enclosure 118 can be liquid or viscous. This means that components, such as one or more photovoltaic cells 102 or a structure 110, for example, if this is realized by means of an inserted foil/workpiece, can have a room for movement. Thus, a structure 110 can be shifted relative to the cell gap 104a or relative to one or more photovoltaic cells 102, also by means of other production-related positioning errors.

In order to counteract the problem of displacements, structure 110 can be made wider so that a tolerance for deviations in positioning is given. This means that the subareas 122, which cover the photovoltaic cells 102, can be made larger, thus covering more area of the photovoltaic cells 102.

However, such a widening of structure 110 may also have adverse effects, especially in the case of bifacial/partial bifacial photovoltaic cells. Here, the subareas 122, e.g. the correspondingly wider subareas 122, can shade the reverse side of the photovoltaic cells 102, i.e. the structure 110 can prevent light from reaching the reverse side of the photovoltaic cell 102 to a greater extent and thus contribute to the generation of electrical energy.

In order to counteract this, as shown in the following figures, structure 110 has a varying covering.

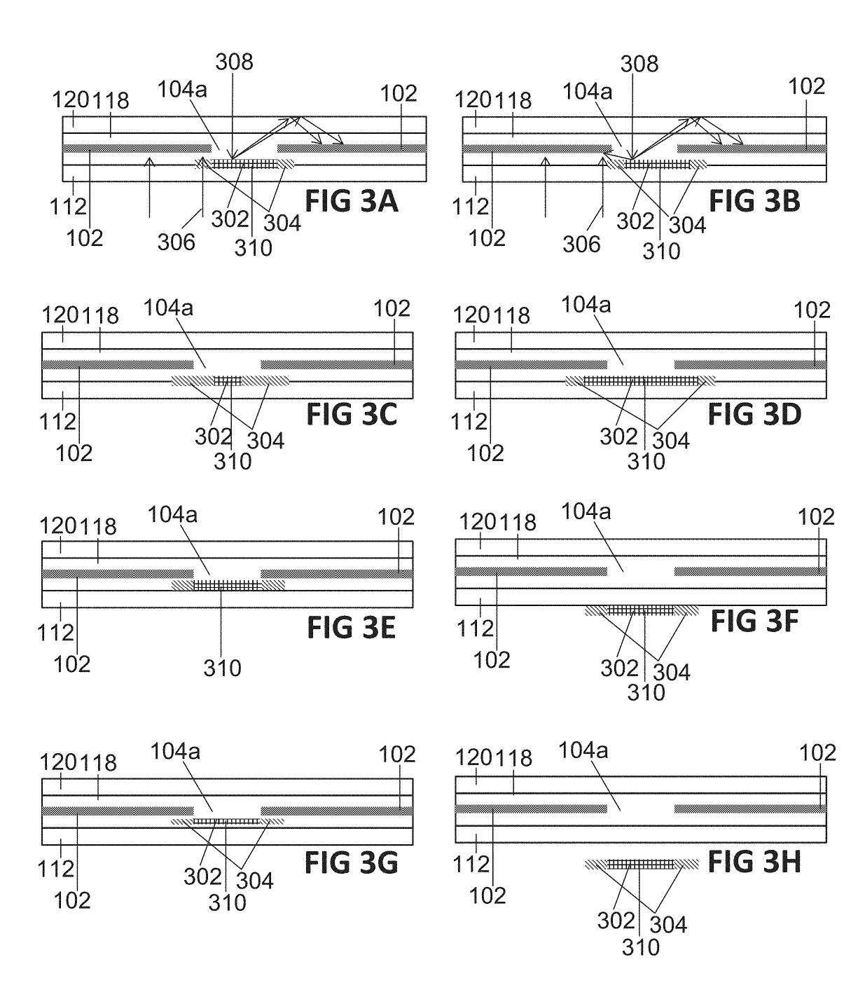

The figures FIG. 3A to FIG. 3H show schematic sections of cross-sections of photovoltaic modules 100 according to various examples. For simplicity's sake, these examples use the same reference signs for the photovoltaic module 100, the front cover 120, the encapsulation 118, the rear cover 112, the cell gap 104a and the photovoltaic cells 102. However, structure 310 is denoted differently for a more detailed description, and sub areas 302 and 304 denote areas with different covering properties.

FIG. 3A shows a similar section as the sections shown in FIG. 2A or FIG. 1B.

In this case, a structure 310 has a subarea 302 which covers the cell gap 104a and a subarea 304 which covers at least one (here two) photovoltaic cells 102. A light beam 308 is also shown, which arrives at the structure 310 from the front of the photovoltaic module 100 into the cell gap 104a, and a light beam 306 which arrives at the structure 310 from the rear of the photovoltaic module 100.

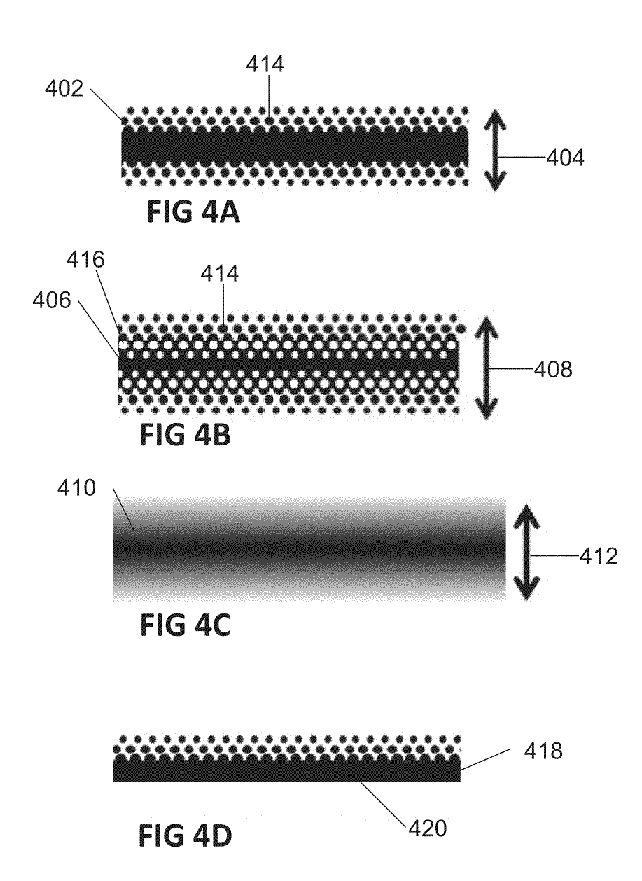

In this example, subarea 302 of structure 310 is completely covered (non-transparent) and subarea 304 has varying coverage. For example, the coverage of the left subarea 304 in the sense of the figure decreases along the direction from the cell gap 104a to the left photovoltaic cell (and in analogy, the coverage of the right subarea 304 decreases towards the right photovoltaic cell 102). Further examples of a varying covering are described in the figures FIG. 4A to FIG. 4D.

The light of the light beam 306 thus reaches at least partially onto the back of the solar cell 102 instead of being completely reflected (or absorbed or a mixture of absorbed and reflected) instead of being reflected by the structure 310 due to the varying degree of coverage in the subarea 304.

Such a varying coverage in subarea 304 of structure 310 can affect several species. On the one hand, there is a tolerance to production-related positioning errors due to the presence of subarea 304 as described above. For example, FIG. 3B shows the cross-section of FIG. 3A with the difference that structure 310 is shifted. The light beam 308 hits the structure 310 despite a shift in structure 310 compared to cell gap 104a. Furthermore, light (e. g. light beam 306), which arrives from the rear of the photovoltaic module 100, can at least partially reach the rear of the photovoltaic cell 102 through the subarea 304. Furthermore, light, which falls from the front side into the gap 104a similar to the light beam 308, can also be reflected at a partial area 304 and thus contribute to the generation of electrical energy.

By means of the variable coverage, for example variable in the sense of a mathematical function (e. g. a continuous function or a staircase function), with which the coverage decreases via structure 310, a parameter or a parameter field is given with which a compensation/compromise between the expected production properties (inaccuracies/tolerances etc.) and the resulting shadowing on the back of a photovoltaic cell 102 and reflection towards the front of the photovoltaic cell 102 can be achieved.

Furthermore, to acceptance of photovoltaic modules 100 can be increased by varying the coverage. In photovoltaic modules, photovoltaic cells 102 can be shifted against each other for production reasons. Such a shift, i. e. in the range of less than 3 mm, can be such that the edges of several photovoltaic cells 102 do not close all of them flush to a given line. Despite its unrestricted functionality, such a photovoltaic module 100 can be classified as a “B-goods” in the trade and thus suffer a corresponding loss of value. The optical impression for the human eye of such a shift is enhanced, for example, by the fact that 102 current collection structures, such as fine metallic structures (also known as fingers, for example, with a width of less than 0.5 mm) can be attached to the back of several photovoltaic cells. If two photovoltaic cells with such current collection structures are installed next to each other in modules, a small shift against each other (move of less than 1 mm) is clearly visible to the human eye. Structure 310 can accordingly be designed/formed according to various examples in such a way that the optical impression of displacement is reduced for the human eye while maintaining other properties of the module.

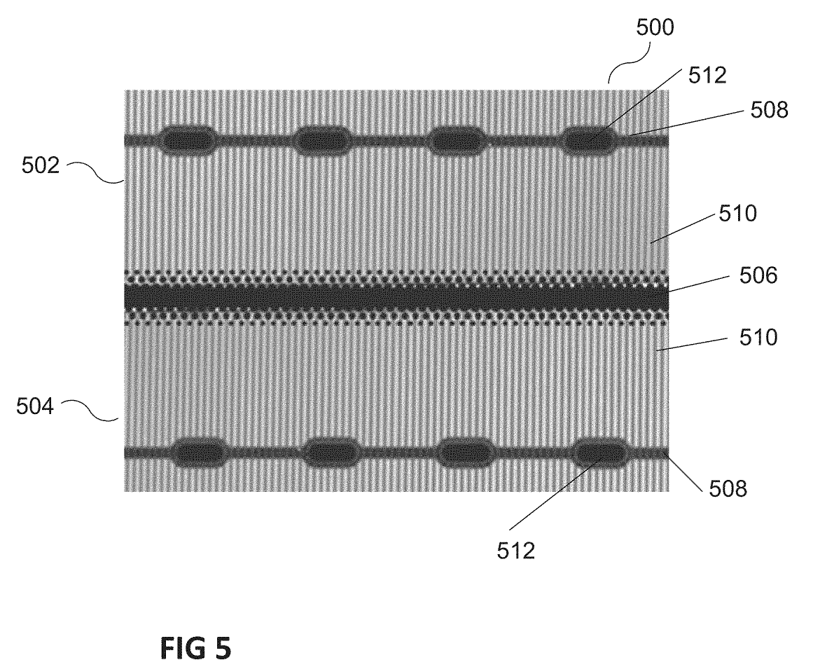

The optical impression could also be reduced, for example, by widening a cell gap of 104a between two photovoltaic cells 102. However, this also reduces the power per area of the photovoltaic module 100. On the other hand, with partial areas 304 with varying coverage, such an optical impression can be produced without widening a cell gap or marginal gap and without limiting the power of the photovoltaic module 100. By varying the covering, the silhouette of a photovoltaic cell 102 or a silhouette of the structures on a photovoltaic cell 102 can be made less perceptible to the human eye. For example, by varying the covering, edges can be concealed, as shown in FIG. 5, for example.

The shown examples can also be combined. For example, it is possible to combine a variation of the size of the subareas 304 in terms of the figures FIG. 3A, FIG. 3B, FIG. 3C and FIG. 3D with a variation of the position of the structure 310 in terms of the figures FIG. 3E, FIG. 3F, FIG. 3G and FIG. 3H.

FIG. 3C shows the section of FIG. 3A, whereby the size and area of the subareas 302 and 304 have been varied.

The sub areas 304 with varying coverage can, as shown, be located in such a way that they cover at least partially the cell gap 104a.

In various examples, the subarea 302 with a constant coverage (e. g. completely non-transparent) cannot exist either, so that in the sense of the figure the left and the right subarea 304 are directly adjacent to each other.

Subareas 304 can also be asymmetrical. In the sense of the figure, the left subarea 304 can be larger than the right subarea 304 (and vice versa). The subareas can also have different coverage distributions. For example, in cases where a preferred direction of displacement is to be expected for production reasons, compensation can be achieved without excessive shading.

Depending on the (expected) production conditions, the 302 subarea may also be larger than the 304 (single and/or added) subareas, as shown in FIG. 3.3. For example, subarea 302 can cover at least one photovoltaic cell 102 at least partially.

The figures FIG. 3E to FIG. 3H show the section of FIG. 3A, whereby structure 310 and thus the sub areas 302,304 of structure 310 are arranged differently in their positions.

Depending on the position of the structure 310, it can be manufactured in different ways, attached and have corresponding other properties, e.g. depending on the distance of the structure 310 from the photovoltaic cells 102 with regard to the reflection and shading of incident light.

In the figures FIG. 3A to FIG. 3D, structure 310 is shown at least partially within the rear cover 112. This can be achieved, for example, by producing structure 310 by means of a paint or paste, such as glass frit or ceramic frit. The rear cover 112 can also have pre-fabricated recesses/ditches to position the structure 310 in it.

FIG. 3E shows the structure 310, which is mounted inside the enclosure 118 on the rear cover 112. For example, structure 310 can be in direct contact with the rear cover 112.

For example, structure 310 may have one or more foils glued to the back cover 112 or may be printed on the back cover 112. Structure 310 can also be attached to the rear cover 112 by means of encapsulation 118.

FIG. 3F shows the structure 310, which compared to the structure 310 of FIG. 3E is mounted on the opposite surface of the rear cover 112. For example, structure 310 can be in direct contact with the rear cover 112.

For example, structure 310 can be installed in the photovoltaic module 102 after mounting the rear cover 112, for example as one of the last steps in the production of the photovoltaic module 102. The structure 310 and the position of structure 310 can be adapted to the position of photovoltaic cells 102, for example after encapsulating the photovoltaic cells 102.

Compared to the structure 310 of FIG. 3E, the structure 310 of FIG. 3F is at a greater distance from the photovoltaic cells 102.

In general, the distance between structure 310 and photovoltaic cells 102 can influence the optical reflection paths and thus the light yield of the photovoltaic module 100. For example, if light falls onto the front and/or rear of the photovoltaic module 100 at an angle, e. g. due to the migration of the position of the sun, a further distant structure 310 can cause more shadowing. However, a more distant structure 310 can also direct more light (e. g. in the sense of the reflected light beam 216 from FIG. 2A) to the rear of a photovoltaic cell 102. Furthermore, a distance, especially if the structure 310 is electrically conductive, may be necessary to avoid short-circuits and the increase of electrical resistances in the photovoltaic module 100. The distance can be adjusted according to the desired event, especially the dimensions of the rear cover 112, in order to achieve the desired effects or a compromise/compensation between the described effects.

FIG. 3G shows the structure 310, which is inserted inside the enclosure 118, for example without direct contact with the rear cover 112.

For example, structure 310 in this example can be an inserted foil or a work piece (e.g. a sheet metal or a similarly thin piece of plastic).

FIG. 3H shows the structure 310, which is attached remotely from the rear cover 112.

For example, the photovoltaic module 100 may have a corresponding mounting bracket, which is attached to a module frame, for example, or the module frame itself. The distance of structure 310 can thus be set independently of the dimensions of the rear cover 112.

The figures FIG. 4A, FIG. 4B, FIG. 4C and FIG. 4D schematically show a top view of a structure according to different examples. A black coloration or the darker a subarea is represented, the lower the transparency of the respective area and the higher the coverage (e. g. a black coloration in a subarea can represent an non-transparent area of a structure).

The structure can be formed during a process of manufacturing a photovoltaic module or be a prefabricated structure that can be used in manufacturing.

The structure can be selected on the basis of its optical properties, degree of transparency/coverage and degree of reflection, and can have or consist of one or more suitable materials. The structure may, for example, have or consist of electrically conductive or electrically insulating material, whereby electrically insulating material or a structure with an electrically insulating layer may be preferred to avoid possible short-circuiting in a photovoltaic module.

As illustrated in FIG. 2B, for example, a width of a structure larger than a cell gap can be used to compensate for production-related positioning errors. The structure widths 404,408 and 412 of the structures 402,406 and 410 can correspond to such a width of a structure in various examples. By varying the (average) coverage of structures 402,406 and 410, it is possible to deal with production-related positioning errors in greater detail and in greater detail. For example, the risk of a photovoltaic cell being shifted in relation to a desired position in a manufacturing process of a photovoltaic module can be higher for a small shift and lower for a large shift. The gradient or function of the transparency of structures 402,406 and 410 can be adapted to such factors, so that the best possible but at least better balance between risk avoidance and shading of a photovoltaic cell is achieved.

In principle, a structure, e. g. a structure 402,406 or 410, can be applied to any and both sides (back and front) of a photovoltaic cell, for example attached to a front cover and/or a rear cover.

For example, the structure can be realized by means of several foils or imprints. One or more layers can have different dimensions, materials and layer thicknesses. The transparency of the structure can be set locally. For example, in a laminate, a foil can be wider than a second foil in one direction as a first layer, so that in a first subarea light only passes through the first foil, in another subarea light only passes through the first and second foil, thus realizing areas with different degrees of transparency and coverage.

According to various examples, a structure can be applied by means of a paint or paste, such as a frit, to, within or partly within the back cover. A (local) covering of the structure can be adjusted, for example, by means of the chemical components, dosages, density and/or the print image of the paint or paste. A paint or paste can be applied using a printing process, for example. By means of subsequent tempering, a structure thus created can be firmly connected or formed with (and, for example, within) the rear cover.

According to various examples, the perforation of a foil and the corresponding density of the perforations can be used to adjust a transparency/covering of a structure averaged over an area/area. For example, a second non-perforated foil may also be present on the foil, so that a lower overall transparency is achieved even with perforations.

Different processes for the production of a structure can be, for example, screen printing, sandblasting, etching, pad printing or application, for example by means of a brush. The surface properties of the structure can also be adjusted. The surface can be designed in such a way that light is diffused to it, for example, a rough or textured surface can be produced/formed.

A structure 402 or other examples of structures can be formed by, for example, applying or printing a continuous layer or providing a continuous workpiece, such as a foil or sheet, and subsequently opening the layer or workpiece. The opening of a layer or workpiece can be done by mechanical means such as punching or perforation, laser processing (e. g. laser ablation) or electron beam processing.

FIG. 4A shows schematically a plan view of a structure 402 with a structure width of 404 according to various examples.

Structure 402 can have a large number of structure characteristics 414, whereby structure characteristic 414 is provided with a reference character as an example for the other structure characteristics.

In the case of FIG. 4A, decreasing coverage is achieved by means of a large number of non-transparent or low-transparent structural features 414 which become smaller in area. From the middle of structure 402 to the edge of structure 402, structural features 414 become smaller in area and are increasingly less dense. In this example, structure characteristics 414 are implemented as filled circles and ellipses. In other examples, they can take any other form. This type of structure 402 can be easily created, since structure 402, for example, has only partial areas with a degree of coverage and partial areas without them, but there are no other gradations.

The shape of one or more structural features 414 as non-transparent/low-transparent areas next to transparent areas can effectively deceive the human eye against a visible shift of photovoltaic cells. By means of the structural characteristics 414 of other covering variations, the optical silhouette of a photovoltaic cell for the human eye, for example its edge, is broken up, or the optical silhouette of structures on a photovoltaic cell, for example the pattern of a metallization layer, is broken up.

FIG. 4B shows schematically another plan view of a structure 406 with a structure width of 408 according to various examples.

Structure 406 corresponds to structure 402 of FIG. 4A, the structure 406 having further substructures 416. For example, as shown here, structure characteristics 414 may have additional substructures 416. This can be used, as described in FIG. 4A, to adjust the local (average) coverage as well as to break up the optical silhouette for the human eye.

FIG. 4C shows schematically another plan view of a structure 410 with a structure width of 412 according to various examples.

The example in FIG. 4C shows structure 410 with a transparency that increases continuously from the middle of structure 410 to the edge of structure 410. The degree of increase can be linear, exponential or in the form of another mathematical function, for example, graduated in the form of a step function or as a combination of various mathematical functions.

FIG. 4D schematically shows a plan view of a structure 418 according to various examples.

In this example, structure 418 corresponds to a halved structure 402 of FIG. 2A. Also in different, as for example described, examples of other structures/structural forms, such a structure can show a decreasing covering in only one direction (here in the sense of the figure from bottom to top). Such a structure, such as structure 418, can be provided for a marginal gap and/or a module frame gap, or at least partially covering the marginal gap/module frame gap. For example, the lower edge 420 can be flush with the edge of the photovoltaic module and/or the edge of a module frame. As in the other examples of structures, the areas of structure 418 can cover a photovoltaic cell with low coverage.

FIG. 5 shows a section of a plan view of a photovoltaic module 500 according to various examples.

The photovoltaic module 500 has an upper photovoltaic cell 502 and a lower photovoltaic cell 504. In this example, the two photovoltaic cells 502.504 are identical in construction, which is not necessarily the case in other examples. The two photovoltaic cells 502,504 are separated from each other so that there is a cell gap between the two photovoltaic cells 502,504. This is not visible here, since structure 406 covers both the cell gap and parts of the two photovoltaic cells 502,504.

In this example, a plan view is shown on the reverse side of the photovoltaic module 500 and correspondingly on the reverse side of the two photovoltaic cells 502,504. Each of the photovoltaic cells 502,504 has current collection structures (metallization structures) on the reverse side in the form of busbars 504 and fingers 510. The busbars 504 can be equipped with pads, which enable the busbars 504 and thus the two photovoltaic cells 502,504 and other photovoltaic cells to be connected electrically conductive by means of soldering.

In this example, the two photovoltaic cells 502.504 are slightly offset against each other, which means that the fingers 510 of the two photovoltaic cells 502.504 are no longer exactly flush with each other. Without the structure 508, this would be visually clearly perceptible. Due to the structure 508, however, this optical impression is broken up and the shift of the two photovoltaic cells 502,504 is hardly perceptible to the human eye. Furthermore, as described for example in connection with the figures FIG. 4A to FIG. 4D, a shadowing of the two photovoltaic cells 502,504 is counterbalanced against production-related positioning errors.

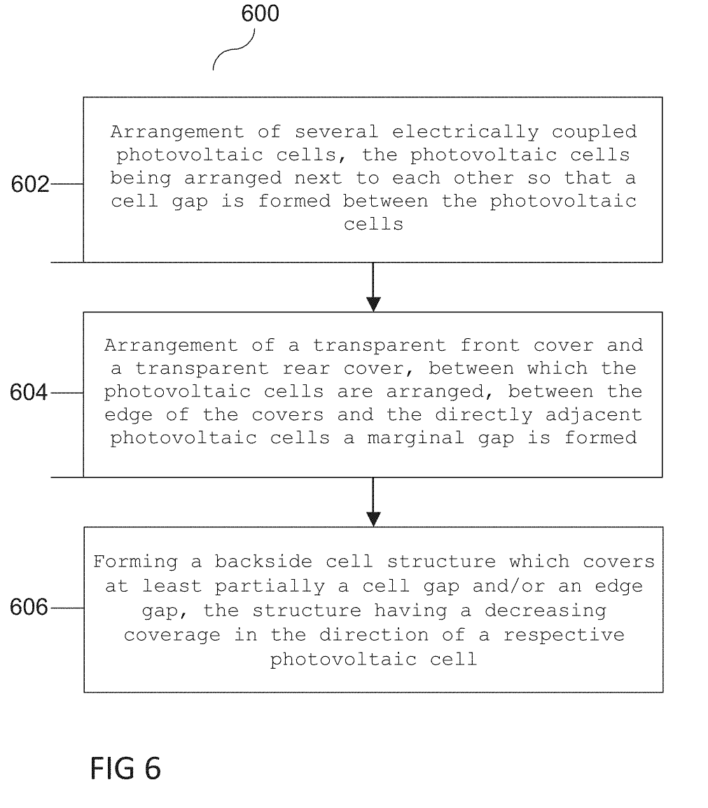

FIG. 6 shows a block diagram 600 of a process for manufacturing a photovoltaic module according to various examples.

A method of manufacturing a photovoltaic module may, in 602, include arranging a plurality of electrically coupled photovoltaic cells, the photovoltaic cells being arranged next to each other so that a cell gap is formed between the photovoltaic cells. Furthermore, the method may further include, in 604, the arrangement of a transparent front cover and a transparent rear cover between which the photovoltaic cells are arranged, a marginal gap being formed between the edge of the covers and the photovoltaic cells directly adjacent thereto. The method may additionally include, in 606, the formation of a cell back structure at least partially covering a cell gap and/or an edge gap, the structure having a decreasing coverage in the direction of a respective photovoltaic cell.

The chronological sequence of the procedure can also be different according to various examples. For example, the cell back side structure can be formed before the photovoltaic module is manufactured and can only be arranged in the photovoltaic module when the photovoltaic module is manufactured.

For other examples, the cell rear structure is carried out before arranging the front or rear panel cover. For example, forming at least part of the structure may involve applying a paint or paste to a back cover and then tempering the back cover, and then arranging the back cover provided with the structure.

According to various embodiments, a photovoltaic module includes or essentially consists of two photovoltaic cells (also called solar cells) or columns between a photovoltaic cell and an edge of the photovoltaic module. Light can pass through such gaps through the photovoltaic module and cannot fall onto a photovoltaic cell, so that this light does not contribute to the generation of electrical energy. The columns increase the area of the photovoltaic module so that the power per area of the photovoltaic module decreases. By means of a structure, such as a layer, in the columns (or covering the columns), the light can be reflected in the columns in different ways, so that this light can contribute to the generation of electrical energy.

For example, in the case of so-called bifacial photovoltaic cells (photovoltaic cells, in which light incidenting on both the front and the back of a photovoltaic cell is used) such structures can, for example, shade the back of the photovoltaic cells, which entails a corresponding reduction in power. This is particularly true because these structures are often wider than the gap to compensate for production-related positioning errors.

According to various embodiments, a photovoltaic module can have several electrically coupled photovoltaic cells, whereby the photovoltaic cells are arranged next to each other so that a cell gap is formed between the photovoltaic cells. In addition, the photovoltaic module can have a transparent front cover and a transparent rear cover, between which the photovoltaic cells are arranged, with a marginal gap being formed between the edge of the covers and the photovoltaic cells directly adjacent to them. In addition, the photovoltaic module may also have a structure on the rear side of the cell which covers at least partially a cell gap and/or an edge gap, the structure having a decreasing coverage in the direction of a respective photovoltaic cell.

By means of a structure that is optically increasingly transparent from a gap along a direction to a photovoltaic cell or has a decreasing coverage, the above situation can be taken into account. By means of a variable coverage as an additional parameter, an expected positioning accuracy can be compared with a resulting shadowing effect and thus the corresponding production conditions can be better accommodated. For example, probabilities with which, for example, various production-related positioning errors with different displacement dimensions occur can be reflected in the variation of the coverage.

In addition, due to production-related positioning errors, photovoltaic cells in a photovoltaic module may also be offset against each other. Even small shifts (e. g. 1 mm and smaller) can be easily visible to the human eye due to metallization structures on photovoltaic cells, for example, and lead to a corresponding photovoltaic module being classified as “B-goods” although the photovoltaic module is not restricted in its functionality. By means of a structure which has a decreasing coverage in the direction of a respective photovoltaic cell, this shift can, however, be considerably less perceptible to the human eye, especially also less perceptible compared to a structure which has a continuous, constant coverage.

Covering here means the ability to prevent light from passing through the structure. Covering can be understood as a counter term to transparency, i.e. when a covering decreases, transparency increases. A complete covering corresponds to an in-transparency. A decreasing covering in one direction can be given by the fact that along this direction the covering decreases locally/punctually. However, a decreasing coverage in one direction can also be given by the fact that an averaged coverage or total coverage, for example a coverage decrease in relation to a sub area/sub surface of the structure.

For example, the structure may have recesses as optically transparent sub areas, so that in an area which has one or more optically transparent sub areas and one or more optically non-transparent sub areas, there is an overall (average) transparency/overall coverage. By means of size, shape and density of the cut-outs, the (local) coverage or transparency can be adjusted and thus indirectly the output can be influenced by incidence of light.

In connection with various examples, non-transparent (non-transparent) or completely covered, for example, a transparency of less than 30%, for example, 20%, for example, less than 10% or less than 5%, can be used.

In various examples, only one cell gap or only one marginal gap is described, but such a description can apply analogously and vice versa to both the cell column and the marginal column.

According to various embodiments, the structure can be completely covered in an area where it covers the cell gap and/or the marginal gap.

According to various embodiments, the structure can have optically transparent and optically non-transparent subareas, whereby the coverage can be adjusted by the ratio of the area content of the optically transparent areas to the area content of the optically non-transparent areas.

Depending on the various embodiments, the back cover may consist of or be made of at least one of the following materials: float glass, rolled glass, Plexi-glass or foil.

For example, a foil can be a single-layer, multi-layer or laminated foil. The foil can also be a cast foil (“cast foil”), for example.

Depending on the different forms of execution, the structure can be made up of one or more layers.

According to various embodiments, the non-transparent areas can be formed by means of a paint or paste.

A paste can, for example, also have or consist of a glass frit and/or ceramic frit.

According to various embodiments, the structure can be realized at least partly by means of one or more foils, whereby at least one foil is at least partially perforated optionally.

According to various embodiments, photovoltaic cells can be bifacial photovoltaic cells.

Bifacial photovoltaic cells can use light, which falls on a front and a back of a photovoltaic cell, to gain electrical energy. For example, a photovoltaic cell can also be partially bifacial, for example, by having only a partial surface of the reverse side of the cell contribute to the generation of electrical energy. However, the embodiments described above can also apply to a photovoltaic module with mono-facial photovoltaic cells, i.e. solar cells with an opaque reverse side.

In accordance with various embodiments, the photovoltaic module can also have a module frame that holds the photovoltaic cells, whereby a module frame gap is formed between the module frame and the photovoltaic cells directly adjacent to it. The structure can at least partially cover a module frame gap.

Various examples and statements about properties and effects can apply to a photovoltaic module as well as analogously to a process for the production of a photovoltaic module and vice versa.

According to various embodiments, a process for manufacturing a photovoltaic module may involve the arrangement of several electrically coupled photovoltaic cells, whereby the photovoltaic cells are arranged next to each other so that a cell gap is formed between the photovoltaic cells. In addition, the method may include arranging a transparent front cover and a transparent rear cover between which the photovoltaic cells are arranged, with a marginal gap being formed between the edge of the covers and the photovoltaic cells directly adjacent thereto.

The method may additionally include forming a backside cell structure which at least partially covers a cell gap and/or an edge gap, the structure having a decreasing coverage in the direction of a respective photovoltaic cell.

According to various embodiments, in a photovoltaic module manufacturing process, the structure may be completely covered in an area where it covers the cell gap and/or the edge gap.

According to various embodiments, the structure of optically transparent and optically non-transparent subareas may have the structure of optically transparent and optically non-transparent subareas in a process for manufacturing a photovoltaic module, and the coverage can be adjusted by the ratio of the area content of the optically transparent areas to the area content of the optically non-transparent areas.

Depending on the various embodiments, the back cover of a photovoltaic module may consist of or be formed of at least one of the following materials: float glass, rolled glass, plexi-glass or laminated foil.

According to various embodiments, the structure of a photovoltaic module can be made up of one or more layers.

According to various embodiments, the structure of a photovoltaic module can be formed after arranging the rear cover in a process for manufacturing a photovoltaic module.

According to various embodiments, in a photovoltaic module manufacturing process, forming at least part of the structure may involve applying a paint or paste to the back cover and then tempering the back cover.

Depending on the various embodiments, the structure of a photovoltaic module may be formed by at least one of the following processes: screen printing, sandblasting, etching, tampon printing or at least partial opening of a previously printed layer.

According to various embodiments, the structure of a photovoltaic module can be at least partly realized by means of one or more foils in a process for the production of a photovoltaic module, whereby at least one foil is or will be perforated at least partially.

According to various embodiments, several electrically coupled photovoltaic cells can be bifacial photovoltaic cells in a process for the production of a photovoltaic module.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A photovoltaic module, comprising:
a plurality of electrically coupled photovoltaic cell, the photovoltaic cells being arranged next to each other such that a cell gap is formed between the photovoltaic cells in each case; and
a transparent front cover and a transparent rear cover between which the photovoltaic cells are arranged, a marginal gap being formed between the edge of the covers and the photovoltaic cells directly adjacent thereto; and
at the back of the cell, a structure which at least partially covers at least one of a cell gap or a marginal gap, the structure having a decreasing coverage in a direction of a respective photovoltaic cell.

2. The photovoltaic module of claim 1,
wherein the structure is completely covered in an area in which it covers at least one of the cell gap or the marginal gap.

3. The photovoltaic module of claim 1,
the structure having optically transparent and optically non-transparent subareas;
wherein the coverage is adjusted by a ratio of optically transparent areas to optically non-transparent areas.

4. The photovoltaic module of claim 1,
wherein the transparent rear cover comprises or is formed of:
float glass; or
rolled glass; or
plexi-glass; or
one or more foils.

5. The photovoltaic module of claim 3,
wherein the non-transparent areas are formed by a paint or paste.

6. The photovoltaic module of claim 1,
wherein the structure is formed of one or more layers.

7. The photovoltaic module of claim 1,
wherein the structure is realized at least partially by one or more foils, at least one foil optionally being at least partially perforated.

8. The photovoltaic module of claim 1,
wherein the photovoltaic cells are bifacial photovoltaic cells.

9. A method of manufacturing a photovoltaic module, the method comprising:
arranging a plurality of electrically coupled photovoltaic cells, the photovoltaic cells being arranged next to each other such that a cell gap is formed between the photovoltaic cells; and
arranging a transparent front cover and a transparent rear cover and photovoltaic cells in between, wherein a marginal gap being formed between the edge of the covers and the photovoltaic cells directly adjacent thereto; and
forming a cell back structure at least partially covering at least one of a cell gap or an edge gap, said structure having a decreasing coverage in a direction of a respective photovoltaic cell.

10. The method of claim 9,
wherein the structure is completely non-transparent in an area in which it covers at least one of the cell gap or the marginal gap.

11. The method of claim 9,
wherein the structure comprises optically transparent and optically non-transparent portions; and
wherein the coverage is adjusted by a ratio of optically transparent areas to optically non-transparent areas.

12. The method of claim 9,
wherein the transparent rear cover comprises or is formed of:
float glass; or
rolled glass; or
plexi-glass; or
one or more foils.

13. The method of claim 9,
wherein the structure is formed of one or more layers.

14. The method of claim 9,
wherein the structure has been formed after arrangement of rear cover.

15. The method of claim 9,
wherein forming of at least a part of the structure comprises application of a paint or paste on the rear cover followed by tempering the rear cover.

16. The method of claim 9,
wherein the structure is formed at least in part by at least one of the following:
screen printing: or
sand blasting; or
etching; or
tampon printing; or
at least partial opening of a previously printed or applied layer.

17. The method of claim 9,
wherein the structure is realized at least partly by one or more foils, at least one foil being perforated at least partly optionally.

18. The method of claim 9,
wherein the several electrically coupled photovoltaic cells are bifacial photovoltaic cells.
